(19) United States
(12) Patent Application Publication
(10) Pub. No.: US 2011/0304310 A1
(43) Pub. Date: Dec. 15, 2011

(54) Multivibrator circuit and voltage converting circuit

(75) Inventor: Takashi Sotono, Kanagawa (JP)

(73) Assignee: Sony Corporation, Tokyo (JP)

(21) Appl. No.: 13/064,982

(22) Filed: Apr. 29, 2011

(30) Foreign Application Priority Data
Jun. 9, 2010 (JP) 2010-131682

(51) Int. Cl. G05F 3/08; H03K 3/281

(52) U.S. Cl. 323/311; 331/113 R

(57) ABSTRACT

The present disclosure provides a multivibrator circuit including: a first field effect transistor; a second field effect transistor; a first resistance; a second resistance; a third resistance; a fourth resistance; a first capacitor; a second capacitor; a diode-connected third field effect transistor; and a diode-connected fourth field effect transistor.

### BACKGROUND

The present disclosure relates to a multivibrator circuit using two field effect transistors and a voltage converting circuit such as a DC (direct current)-to-DC converter or the like.

FIG. 1 is a diagram showing a basic multivibrator circuit using two enhancement mode field effect transistors.

The multivibrator circuit 10 in FIG. 1 is a circuit described as background art in Japanese Patent Laid-Open No. 2006-222487 (hereinafter referred to as Patent Document 1).

The multivibrator circuit 10 has a first enhancement mode field effect transistor (FET) 11, a second FET 12, a first resistance R11, a second resistance R12, a third resistance R13, a fourth resistance R14, a first capacitor C11, and a second capacitor C12.

The multivibrator circuit 10 has nodes ND11, ND12, ND13, and ND14, an output terminal TOUT11 connected to the node ND11, and an output terminal TOUT12 connected to the node ND12.

The sources of the first FET 11 and the second FET 12 are connected to a ground potential GND.

The drain of the first FET 11 is connected to the node ND11. The drain of the second FET 12 is connected to the node ND12.

The gate of the first FET 11 is connected to the node ND14. The gate of the second FET 12 is connected to the node ND13.

The first resistance R11 is connected between a source SVDD of supply of a power supply voltage VDD and the node ND11. The second resistance R12 is connected between the source SVDD of supply of the power supply voltage VDD and the node ND12.

The third resistance R13 is connected between the source SVDD of supply of the power supply voltage VDD and the node ND13. The fourth resistance R14 is connected between the source SVDD of supply of the power supply voltage VDD and the node ND14.

The first capacitor C11 is connected between the node ND11 and the node ND13. The second capacitor C12 is connected between the node ND12 and the node ND14.

This multivibrator circuit 10 is a basic circuit. The functions of the multivibrator circuit 10 are described in Patent Document 1. As is disclosed in Patent Document 1, it is difficult for this circuit to achieve lower voltage and lower power consumption.

A multivibrator circuit that solves this problem is proposed in Patent Document 1.

FIG. 2 is a diagram showing the multivibrator circuit proposed in Patent Document 1.

In the multivibrator circuit 10A in FIG. 2, positions of connection of a third resistance R13 and a fourth resistance R14 are different from those of the multivibrator circuit 10 in FIG. 1.

Specifically, in the multivibrator circuit 10A, the third resistance R13 is connected between the gate and the drain of a first FET 11, and the fourth resistance R14 is connected between the gate and the drain of a second FET 12.

With this configuration, when the gate voltage of the first FET 11 is a logical “H (High),” a current flows from a power source to a ground side via a second resistance R12, a second capacitor C12, the third resistance R13, and the first FET 11 in an on state.

In addition, when the gate voltage of the second FET 12 is a logical value H, a current flows from the power source to the ground side via a first resistance R11, a first capacitor C11, the fourth resistance R14, and the second FET 12 in an on state.

Thereby, the first FET 11 and the second FET 12 gradually decrease in gate voltage.

Thus, a pinch-off voltage can surely be obtained when the gate voltage changes from a logical value H to an L (Low), and stable and reliable oscillation at a low current and a low voltage is ensured.

### SUMMARY

Although the multivibrator circuit in FIG. 2 can achieve lower voltage and lower current consumption, the multivibrator circuit in FIG. 2 has a problem in that oscillation frequency is varied due to variation in transistor characteristics, which results in poor stability of the oscillation frequency.

Thus, the output voltage of a voltage converting circuit (DC-to-DC converter) or the like to which this multivibrator circuit is applied varies due to the oscillation frequency, which results in disadvantages of difficulty in obtaining stable characteristics and a narrower permissible range of FET variation.

It is desirable to provide a multivibrator circuit and a voltage converting circuit capable of stabilizing oscillation frequency even when there is variation in transistor characteristics while achieving lower voltage and lower current consumption.

According to a first viewpoint of the present disclosure, there is provided a multivibrator circuit including: a first field effect transistor having a source connected to a ground potential; a second field effect transistor having a source connected to the ground potential; a first resistance connected between a drain of the first field effect transistor and a source of supply of a power supply voltage; a second resistance connected between a drain of the second field effect transistor and the source of supply of the power supply voltage; a third resistance connected between a gate of the second field effect transistor and the source of supply of the power supply voltage; a fourth resistance connected between a gate of the first field effect transistor and the source of supply of the power supply voltage; a first capacitor connected between the drain of the first field effect transistor and the gate of the second field effect transistor, and forming an integrating circuit with the third resistance; a second capacitor connected between the drain of the second field effect transistor and the gate of the first field effect transistor, and forming an integrating circuit with the fourth resistance; a diode-connected third field effect transistor connected between the gate of the first field effect transistor and the ground potential; and a diode-connected fourth field effect transistor connected between the gate of the second field effect transistor and the ground potential.

According to a second viewpoint of the present disclosure, there is provided a voltage converting circuit including: an oscillating circuit section including a multivibrator circuit for generating a clock of a positive phase and a clock in opposite phase from the clock of the positive phase; and a voltage generating section for generating and outputting a voltage different from a supplied voltage according to the clocks of the positive phase and the opposite phase, the clocks of the positive phase and the opposite phase being supplied from the oscillating circuit section. The multivibrator circuit of the oscillating circuit section includes a first field effect transistor having a source connected to a ground potential, a second field effect transistor having a source connected to the ground potential, a first resistance connected between a drain of the first field effect transistor and a source of supply of a power supply voltage, a second resistance connected between a drain of the second field effect transistor and the source of supply of the power supply voltage, a third resistance connected between a gate of the second field effect transistor and the source of supply of the power supply voltage, a fourth resistance connected between a gate of the first field effect transistor and the source of supply of the power supply voltage, a first capacitor connected between the drain of the first field effect transistor and the gate of the second field effect transistor, and forming an integrating circuit with the third resistance, a second capacitor connected between the drain of the second field effect transistor and the gate of the first field effect transistor, and forming an integrating circuit with the fourth resistance, a diode-connected third field effect transistor connected between the gate of the first field effect transistor and the ground potential, and a diode-connected fourth field effect transistor connected between the gate of the second field effect transistor and the ground potential.

According to the present disclosure, it is possible to stabilize oscillation frequency even when there is variation in transistor characteristics while achieving lower voltage and lower current consumption.

### BRIEF DESCRIPTION OF THE DRAWINGS

FIG. 1 is a diagram showing a basic multivibrator circuit using two enhancement mode field effect transistors;

FIG. 2 is a diagram showing a multivibrator circuit proposed in Patent Document 1;

FIG. 3 is a diagram showing a multivibrator circuit according to a first embodiment of the present disclosure;

FIGS. 4A, 4B, 4C, and 4D are diagrams of assistance in explaining the operation of the multivibrator circuit according to the present embodiment;

FIG. 5 is a diagram showing changes in voltage across a first capacitor;

FIG. 6 is a diagram showing FET characteristics when FET threshold voltage varies;

FIG. 7 is a diagram showing the voltage-current characteristics of a bias circuit when an FET having the characteristics of FIG. 6 is used;

FIGS. 8A, 8B, and 8C are diagrams showing differences in the characteristic of oscillation frequency between the multivibrator circuit according to the present embodiment and a first and a second comparative example by simulation results;

FIGS. 9A, 9B, and 9C are diagrams showing differendes in the characteristic of current consumption between the multivibrator circuit according to the present embodiment and the first and second comparative examples by simulation results;

FIG. 10 is a diagram showing a multivibrator circuit according to a second embodiment of the present disclosure;

FIG. 11 is a block diagram showing an example of configuration of a high-frequency switch circuit according to a third embodiment of the present disclosure;

FIG. 12 is a circuit diagram showing a concrete example of configuration of a voltage converting circuit as a power supply device according to the present embodiment; and

FIG. 13 is a circuit diagram showing a Dickson type charge pump circuit.

### DETAILED DESCRIPTION OF THE PREFERRED EMBODIMENTS

Preferred embodiments of the present disclosure will hereinafter be described with reference to the drawings.

Incidentally, description will be made in the following order.

1. First Embodiment (First Example of Configuration of Multivibrator Circuit)

2. Second Embodiment (Second Example of Configuration of Multivibrator Circuit)

3. Third Embodiment (Example of Configuration of High-Frequency Switch Circuit)

### 1. First Embodiment

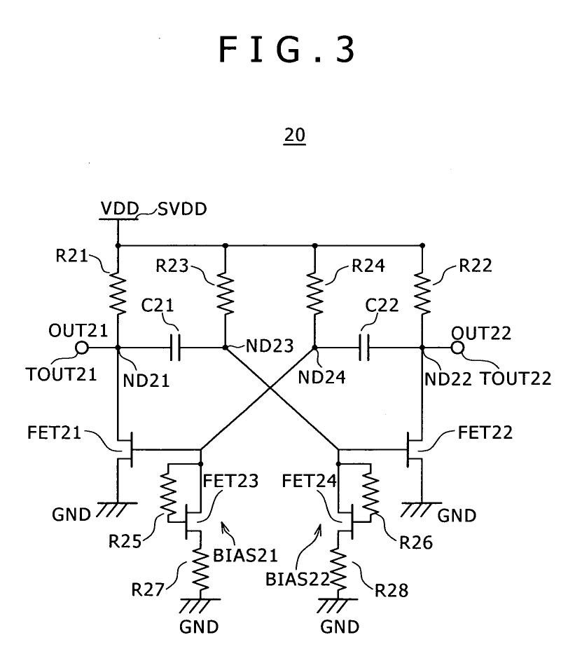

FIG. 3 is a diagram showing a multivibrator circuit according to a first embodiment of the present disclosure.

As shown in FIG. 3, the multivibrator circuit 20 according to the present first embodiment has a first enhancement mode FET (field effect transistor) 21, a second FET 22, a third FET 23, and a fourth FET 24.

The multivibrator circuit 20 has a first resistance R21, a second resistance R22, a third resistance R23, a fourth resistance R24, a fifth resistance R25, a sixth resistance R26, a seventh resistance R27, an eighth resistance R28, a first capacitor C21, and a second capacitor C22.

The multivibrator circuit 20 has a node ND21, a node ND22, a node ND23, a node ND24, an output terminal TOUT21 connected to the node ND21, and an output terminal TOUT22 connected to the node ND22.

The sources of the first FET 21 and the second FET 22 are connected to a ground potential GND.

The drain of the first FET 21 is connected to the node ND21. The drain of the second FET 22 is connected to the node ND22.

The gate of the first FET 21 is connected to the node ND24. The gate of the second FET 22 is connected to the node ND23.

The first resistance R21 is connected between a source SVDD of supply of a power supply voltage VDD and the node ND21. The second resistance R22 is connected between the source SVDD of supply of the power supply voltage VDD and the node ND22.

The third resistance R23 is connected between the source SVDD of supply of the power supply voltage VDD and the node ND23. The fourth resistance R24 is connected between the source SVDD of supply of the power supply voltage VDD and the node ND24.

The first capacitor C21 is connected between the node ND21 and the node ND23. The second capacitor C22 is connected between the node ND22 and the node ND24.

The drain of the third FET 23 is connected to the gate of the first FET 21 and the node ND24. The gate and the drain of the third FET 23 are connected to each other via the fifth resistance R25. The source of the third FET 23 is connected to the ground potential GND via the seventh resistance R27.

The drain of the fourth FET 24 is connected to the gate of the second FET 22 and the node ND23. The gate and the drain of the fourth FET 24 are connected to each other via the sixth resistance R26. The source of the fourth FET 24 is connected to the ground potential GND via the eighth resistance R28.

In the multivibrator circuit 20, the diode-connected third FET 23 whose gate and drain are connected to each other by the fifth resistance R25 is connected to the gate part of the first FET 21.

Similarly, the diode-connected fourth FET 24 whose gate and drain are connected to each other by the sixth resistance R26 is connected to the gate part of the second FET 22.

The diode-connected third FET 23 and the diode-connected fourth FET 24 have characteristics identical to those of the first FET 21 and the second FET 22.

The multivibrator circuit 20 thereby stabilizes oscillation frequency dependent on the characteristics of the FETs, for example threshold value variations.

Incidentally, the resistance values of the fifth resistance R25, the sixth resistance R26, the seventh resistance R27, and the eighth resistance R28 are sufficiently smaller than the resistance values of the third resistance R23 and the fourth resistance R24.

For example, the resistance values of the fifth resistance R25 and the sixth resistance R26 are about 1/20 of the resistance values of the third resistance R23 and the fourth resistance R24.

The resistance values of the seventh resistance R27 and the eighth resistance R28 are about 1/15 of the resistance values of the third resistance R23 and the fourth resistance R24.

In the multivibrator circuit 20, the third FET 23, the fifth resistance R25, and the seventh resistance R27 form a first bias circuit BIAS21.

The fourth FET 24, the sixth resistance R26, and the eighth resistance R28 form a second bias circuit BIAS22.

The same corresponding parts of the first bias circuit BIAS21 and the second bias circuit BIAS22 are configured with same constants.

The fifth resistance R25 is disposed to control a flow of current to the gate of the third FET 23. The sixth resistance R26 is disposed to control a flow of current to the gate of the fourth FET 24.

The seventh resistance R27 is disposed for bias adjustment of the first bias circuit BIAS21. The eighth resistance R28 is disposed for bias adjustment of the second bias circuit BIAS22.

The bias circuits BIAS21 and BIAS22 drop gate voltages at a time of forward-direction operation using the diode connections of the third FET 23 and the fourth FET 24 having characteristics identical to those of the first FET 21 and the second FET 22 of the multivibrator circuit.

Thereby, the bias circuits BIAS21 and BIAS22 have a feature of changing charging voltages to the capacitors C21 and C22 by the FET characteristics, and stabilizing the oscillation frequency.

In addition, the diode characteristic bias circuits perform opposite-direction operation at a time of transition of the gate voltages to negative voltage. The bias circuits BIAS21 and BIAS22 therefore have a feature of eliminating effects of the bias circuits BIAS21 and BIAS22 at a time of operation of an RC integrating circuit from the negative voltage by setting the gate voltages in an insulated state.

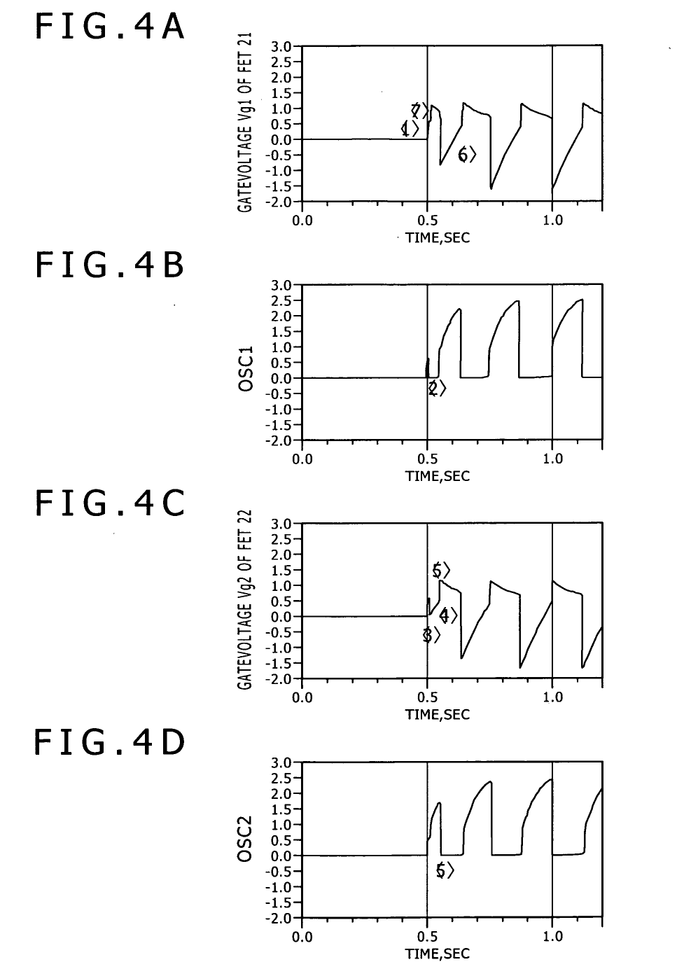

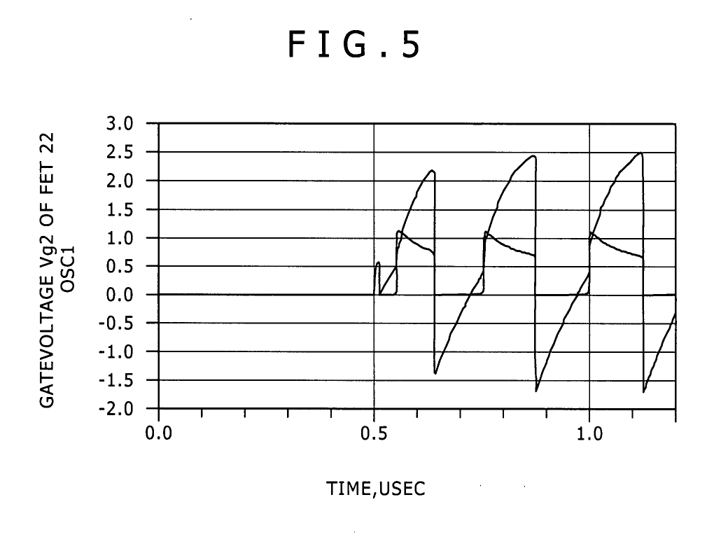

A concrete operation of the multivibrator circuit 20 having such features will next be described with reference to FIGS. 4A to 4D and FIG. 5.

FIGS. 4A to 4D are diagrams of assistance in explaining the operation of the multivibrator circuit according to the present embodiment.

FIG. 4A shows the gate voltage Vg1 of the first FET 21. FIG. 4B shows the drain voltage (first output signal) OSC1 of the first FET 21. FIG. 4C shows the gate voltage Vg2 of the second FET 22. FIG. 4D shows the drain voltage OSC2 of the second FET 22.

<1>: The gate voltage Vg1 of the first FET 21 rises through the fourth resistance R24. The gate voltage Vg2 of the second FET 22 rises through the third resistance R23.

<2>: The gate voltage Vg1 of the first FET 21 exceeds a threshold value Vth to turn on the first FET 21, and the drain voltage OSC1 of the first FET 21 makes a sharp transition to a ground level.

Incidentally, the gate voltage Vg1 of the first FET 21 thereafter rises sharply through the second capacitor C22 due to a rise in the drain voltage OSC2 of the second FET 22, but falls gradually due to a forward-direction current produced by the first bias circuit BIAS21.

<3>: In parallel with this, the gate voltage Vg2 of the second FET 22 also makes a sharp transition to Ground Level (dependent on the on resistance of the first FET 21 and the first resistance R21) −Vc21 through the first capacitor C21 (charging voltage Vc21).

In this case, the gate voltage Vg2 of the second FET 22 immediately before the transition is voltage-divided by a forward-direction component Vf of the diode connection and a resistance component of the eighth resistance R28 of the second bias circuit BIAS22. At this time, Vg2<OUT21 is maintained, and the charging voltage (Vc21) of the first capacitor C21 is made to be high. However, at a start of oscillation, the first capacitor C21 is not fully charged, and thus a small drop occurs.

<4>: The gate voltage Vg2 of the second FET 22 after the transition is at −Vc21, and is charged by an integrating circuit formed by the third resistance R23 and the first capacitor C21.

In this case, the gate voltage Vg2 of the second FET 22 after the transition is −Vc21, and is set in an insulated state by an opposite-direction characteristic of the diode connection of the second bias circuit BIAS22. An integrating operation at this time is performed by the third resistance R23 and the first capacitor C21 with little effect of the second bias circuit BIAS22.

<5>: The gate voltage Vg2 of the second FET 22 exceeds a threshold value Vth to thereby turn on the second FET 22, and the drain voltage OSC2 of the second FET 22 makes a sharp transition to the ground level.

Incidentally, the gate voltage Vg2 of the second FET 22 thereafter rises sharply through the first capacitor C21 due to a rise in the drain voltage OSC1 of the first FET 21, but falls gradually due to a forward-direction current produced by the bias circuit BIAS22.

<6>: In parallel with this, the gate voltage Vg1 of the first FET 21 also makes a sharp transition to Ground Level (dependent on the on resistance of the second FET 22 and the second resistance R22) −Vc22 through the second capacitor C22 (charging voltage Vc22).

In this case, the gate voltage Vg1 of the first FET 21 before the transition is voltage-divided by a forward-direction component Vf of the diode connection and a resistance component of the seventh resistance R27 of the bias circuit BIAS21, Vg1<OUT22 is maintained, and the charging voltage (Vc22) of the second capacitor C22 is high.

<7>: The gate voltage Vg1 of the first FET 21 after the transition is at −Vc22, and is charged by an integrating circuit formed by the fourth resistance R24 and the second capacitor C22.

In this case, the gate voltage Vg1 of the first FET 21 after the transition is −Vc22, and is set in an insulated state by an opposite-direction characteristic of the diode connection of the bias circuit BIAS21, and an integrating operation is performed by the fourth resistance R24 and the second capacitor C22.

By repeating the operation shown in the above <2> to <7>, oscillating operation is continued and set in a steady state, and the oscillation frequency is stabilized.

Changes in voltage across the first capacitor C21 in the above operation will be considered with reference to FIG. 5.

FIG. 5 is a diagram showing changes in voltage across the first capacitor C21, and is a diagram showing the image of the drain voltage OSC1 of the first FET 21 in FIG. 4B and the image of the gate voltage Vg2 of the second FET 22 in FIG. 4C in a state of being superimposed on each other.

A potential (voltage) on the side of one terminal of the first capacitor C21 which terminal is connected to the node ND21 (drain of the first FET 21) rises with a time constant of the first resistance R21 and the first capacitor C21 when the first FET 21 is off.

A potential (voltage) on the side of another terminal of the first capacitor C21 which terminal is connected to the node ND23 (gate of the second FET 22) gradually falls due to the voltage division of the second bias circuit BIAS22.

A potential difference between the drain voltage OSC1 of the first FET 21 and the gate voltage Vg2 of the second FET 22 immediately before switching is regarded as a voltage with which the first capacitor C21 is charged.

After the switching, the drain voltage OSC1 of the first FET 21 falls to the level of the ground potential GND, and the gate voltage Vg2 of the second FET 22 falls to a negative side by the amount of the voltage with which the first capacitor C21 is charged.

Incidentally, the charging voltage of the first capacitor C21 can be set so as to be surely lower than the threshold voltage Vth of the second FET 22.

The charging voltage of the second capacitor C22 operates in a similar manner to the above.

Specifically, a potential (voltage) on the side of one terminal of the second capacitor C22 which terminal is connected to the node ND22 (drain of the second FET 22) rises with a time constant of the second resistance R22 and the second capacitor C22 when the second FET 22 is off.

A potential (voltage) on the side of another terminal of the second capacitor C22 which terminal is connected to the node ND24 (gate of the first FET 21) gradually falls due to the voltage division of the bias circuit BIAS21.

A potential difference between the drain voltage OSC2 of the second FET 22 and the gate voltage Vg1 of the first FET 21 immediately before switching is regarded as a voltage with which the second capacitor C22 is charged.

After the switching, the drain voltage OSC2 of the second FET 22 falls to the level of the ground potential GND, and the gate voltage Vg1 of the first FET 21 falls to a negative side by the amount of the voltage with which the second capacitor C22 is charged.

Incidentally, the charging voltage of the second capacitor C22 can be set so as to be surely lower than the threshold voltage Vth of the first FET 21.

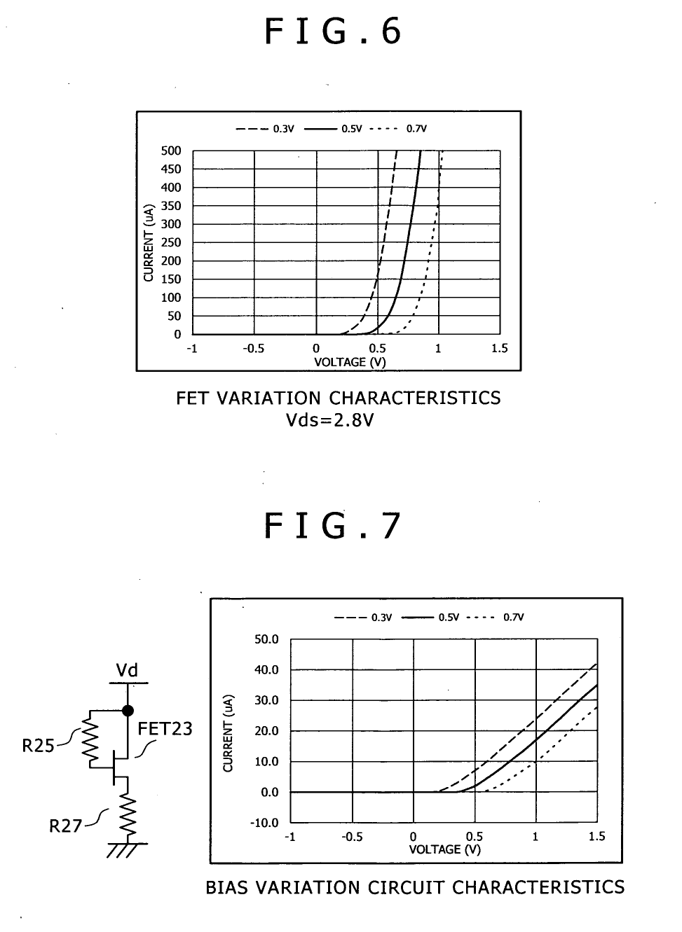

FIG. 6 is a diagram showing FET characteristics when FET threshold voltage varies.

FIG. 7 is a diagram showing the voltage-current characteristics of a bias circuit when an FET having the characteristics of FIG. 6 is used.

As described above, the first and second FETs 21 and 22 of the multivibrator circuit 20 and the third and fourth FETs 23 and 24 of the bias circuits BIAS21 and BIAS22 have identical characteristics.

Thus, when the threshold value Vth of the FET varies, bias voltage also exhibits variation depending on the threshold value Vth.

At the times of operation of the above <3> and <6>, the voltages applied to the capacitors C21 and C22 are high when the threshold value Vth is low, and are low when the threshold value Vth is high.

This difference in the applied voltages appears in negative voltage values to which the gate voltage Vg2 of the second FET 22 and the gate voltage Vg1 of the first FET 21 make transition at the times of operation of the above <4> and <7>.

At this time, the negative voltage values to which the transition is made are high when the threshold value Vth is low, and are low when the threshold value Vth is high.

Oscillation frequency is determined by a reciprocal of a time to reach, from the negative voltage values given by the RC integrating circuits, the threshold values Vth of the first FET 21 and the second FET 22 of the multivibrator circuit (oscillating circuit).

In this case, the RC integrating circuits are formed by the third resistance R23 and the first capacitor C21 as well as the fourth resistance R24 and the second capacitor C22.

The present embodiment achieves stability of the oscillation frequency by suppressing a voltage difference of negative voltage −FET Vth due to a difference in the characteristic of the threshold value Vth of the FET by using a diode-connected FET in the bias circuits BIAS21 and BIAS22.

Differences in the characteristics of oscillation frequency and current consumption between the multivibrator circuit 20 according to the present embodiment and a first and a second comparative example (1) and (2) will next be shown by simulation results.

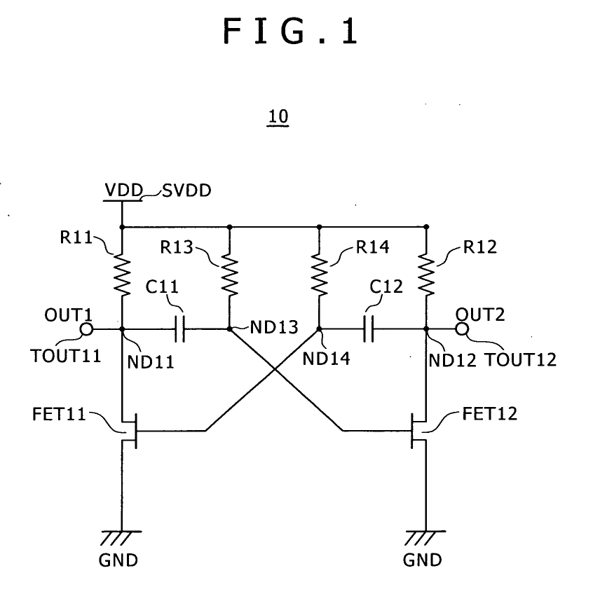

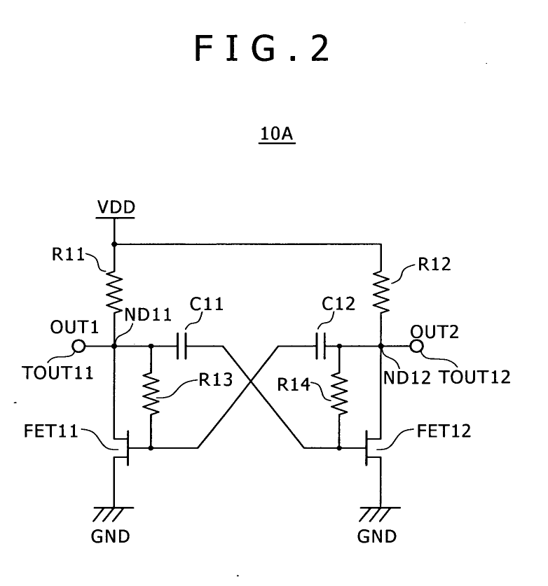

In this case, the multivibrator circuit 10 of FIG. 1 was applied as the first comparative example (1), and the multivibrator circuit 10A of FIG. 2 was applied as the second comparative example (2).

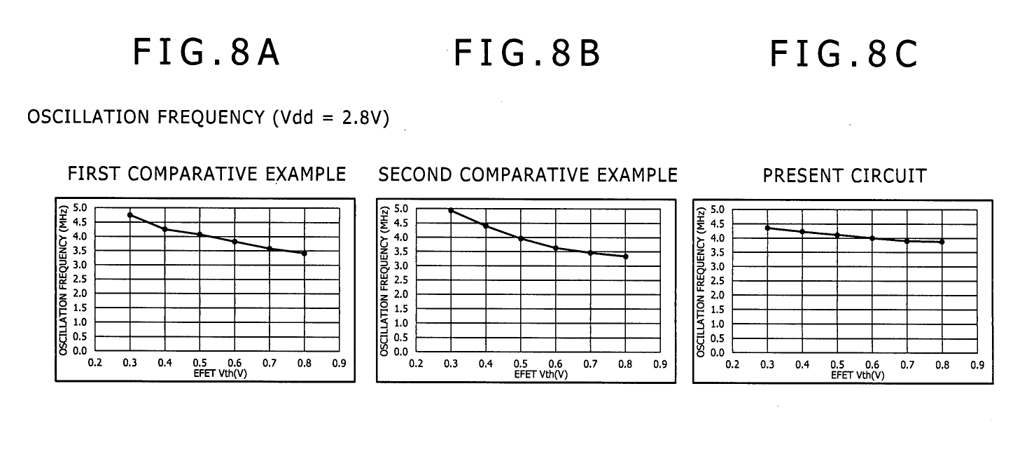

FIGS. 8A to 8C are diagrams showing differences in the characteristic of oscillation frequency between the multivibrator circuit 20 according to the present embodiment and the first and second comparative examples (1) and (2) by simulation results.

FIG. 8A shows the simulation result of the first comparative example (1). FIG. 8B shows the simulation result of the second comparative example (2). FIG. 8C shows the simulation result of the multivibrator circuit (present circuit) according to the present embodiment.

In FIGS. 8A to 8C, an axis of abscissas indicates an FET threshold value Vth, and an axis of ordinates indicates oscillation frequency.

As is understood from FIGS. 8A to 8C, the multivibrator circuit 20 according to the present embodiment can suppress variation in oscillation frequency as compared with the first and second comparative examples (1) and (2) by the functions of the bias circuits BIAS21 and BIAS22.

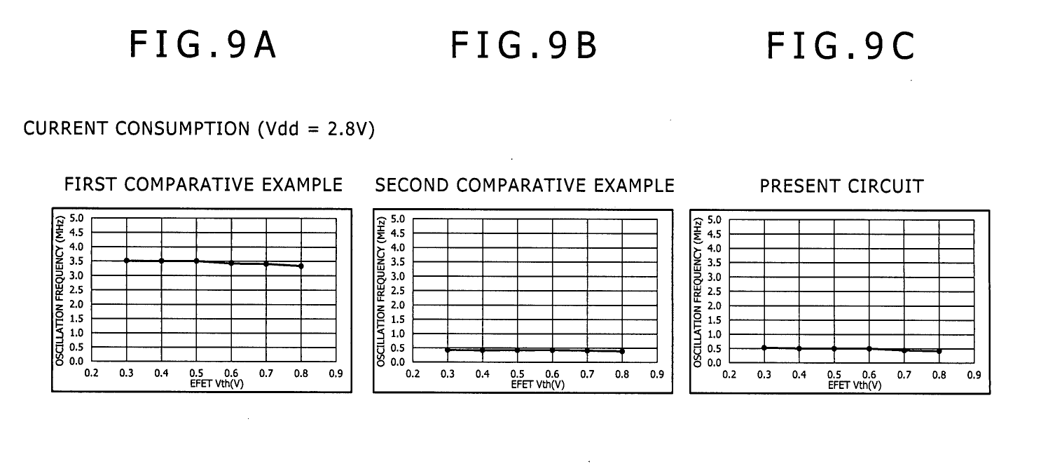

FIGS. 9A to 9C are diagrams showing differences in the characteristic of current consumption between the multivibrator circuit 20 according to the present embodiment and the first and second comparative examples (1) and (2) by simulation results.

FIG. 9A shows the simulation result of the first comparative example (1). FIG. 9B shows the simulation result of the second comparative example (2). FIG. 9C shows the simulation result of the multivibrator circuit (present circuit) according to the present embodiment.

In FIGS. 9A to 9C, an axis of abscissas indicates an FET threshold value Vth, and an axis of ordinates indicates current consumption.

As is understood from FIGS. 9A to 9C, the multivibrator circuit 20 according to the present embodiment can achieve low current consumption equal to that of the second comparative example (2) by the functions of the bias circuits BIAS21 and BIAS22.

### 2. Second Embodiment

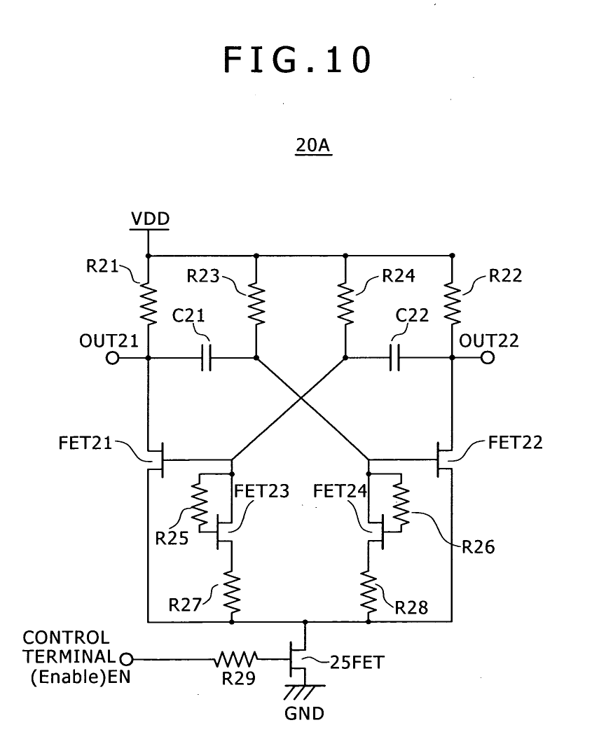

FIG. 10 is a diagram showing a multivibrator circuit according to a second embodiment of the present disclosure.

The multivibrator circuit 20A according to the present second embodiment is different from the multivibrator circuit 20 according to the first embodiment in the following respects.

The multivibrator circuit 20A has a fifth FET 25 functioning as a switch which fifth FET 25 is disposed between the sources of a first FET 21 and a second FET 22 and the ground side terminals of a seventh resistance R27 and an eighth resistance R28 and a ground potential GND.

The source of the fifth FET 25 is connected to the ground potential GND. The drain of the fifth FET 25 is connected to the sources of the first FET 21 and the second FET 22 and the ground side terminals of the seventh resistance R27 and the eighth resistance R28.

The gate of the fifth FET 25 is connected via a ninth resistance R29 to a control terminal TC to which an enable signal EN is supplied.

The multivibrator circuit 20A can turn on the fifth FET 25 only at a time of operation and turn off the fifth FET 25 at a time of non-operation, and thus achieve even lower power consumption.

### 3. Third Embodiment

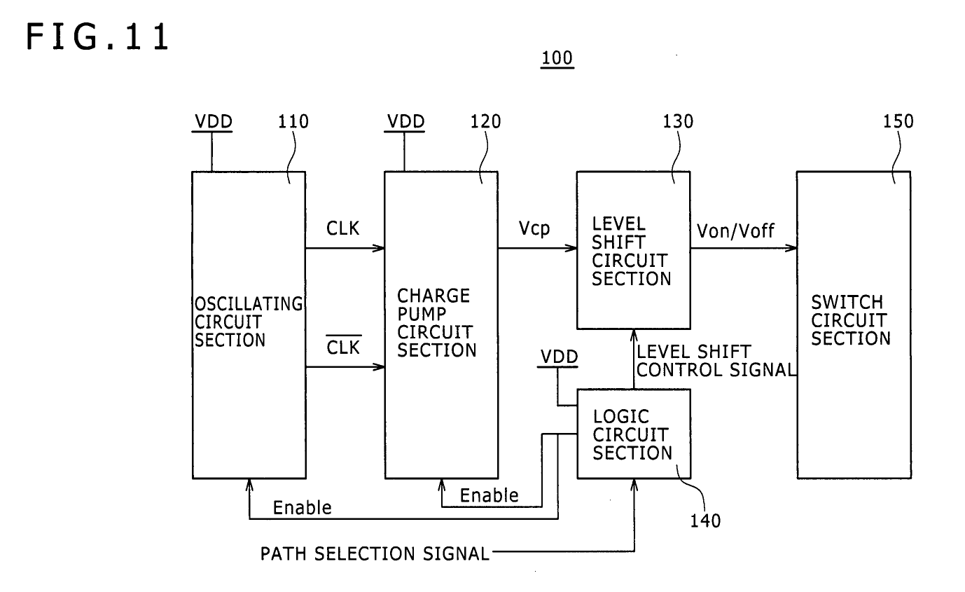

FIG. 11 is a block diagram showing an example of configuration of a high-frequency switch circuit according to a third embodiment of the present disclosure.

The high-frequency switch circuit 100 in FIG. 11 is applicable as a high-frequency switch circuit for connecting transmitting and received signals of a portable telephone or the like to a desired path.

The high-frequency switch circuit 100 in FIG. 11 has an oscillating circuit section 110, a charge pump circuit section 120, a level shift circuit section 130, a logic circuit section 140, and a switch circuit section 150.

In the high-frequency switch circuit 100 in FIG. 11, the multivibrator circuit 20 or 20A according to the first embodiment or the second embodiment described above is applied as the oscillating circuit section 110.

In the high-frequency switch circuit 100, the oscillating circuit section 110 supplies clocks CLK and /CLK (/ denotes an opposite phase) of a positive phase and an opposite phase to the charge pump circuit section 120 in a simultaneous and parallel manner.

On the basis of the oscillation frequency of the oscillating circuit section 110, the charge pump circuit section 120 generates a voltage Vcp (step-up power or negative power) different from a power supply voltage VDD supplied from the terminal. The charge pump circuit section 120 supplies the voltage Vcp to the level shift circuit section 130.

The level shift circuit section 130 supplies the voltage Vcp to the switch circuit section 150 on the basis of a level shift control signal from the logic circuit section 140.

The oscillating circuit section 110 and the charge pump circuit section 120 form a voltage converting circuit (DC-to-DC converter: hereinafter a DDC) 200 as a power supply device.

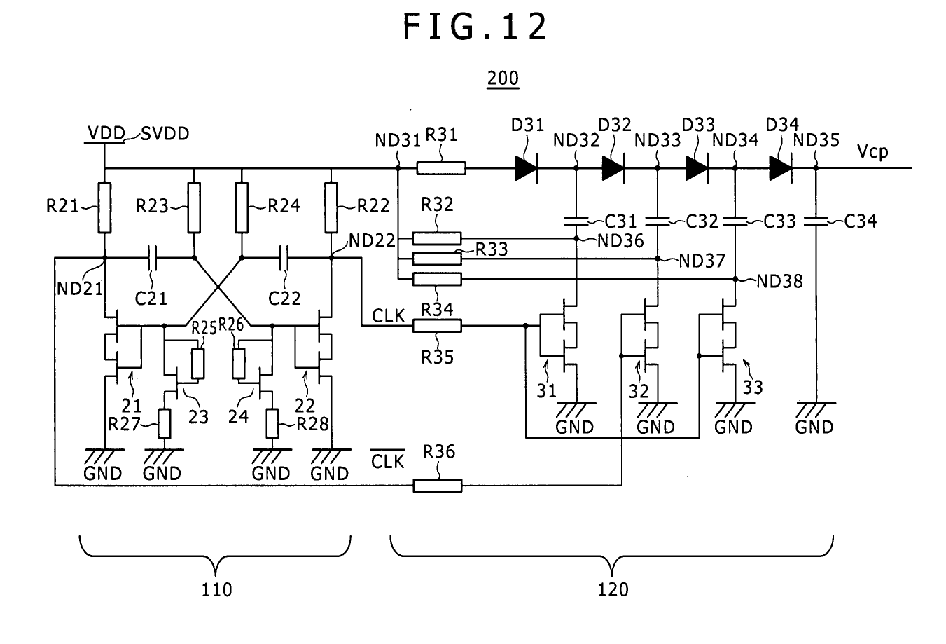

FIG. 12 is a circuit diagram showing a concrete example of configuration of the voltage converting circuit as the power supply device according to the present embodiment.

As described above, the voltage converting circuit 200 in FIG. 12 is formed by the oscillating circuit section 110 and the charge pump circuit section 120.

The multivibrator circuit 20 in FIG. 3 according to the first embodiment is applied to the oscillating circuit section 110 in FIG. 12.

In FIG. 12, each constituent element of the oscillating circuit section 110 is identified by the same reference numeral as in FIG. 3 to facilitate understanding.

However, a first FET 21 and a second FET 22 are each formed by cascading two FETs. The first FET 21 and the second FET 22 are functionally similar to those of the already described multivibrator circuit 20.

The oscillating circuit section 110 oscillates and outputs a clock CLK of a positive phase from a node ND22 (drain of the second FET 22), and oscillates and outputs a clock /CLK of an opposite phase from a node ND21 (drain of the first FET 21).

The charge pump circuit section 120 includes FETs 31, 32, and 33 as switches, diodes D31 to D34, resistances R31 to R36, capacitors C31, C32, C33, and C34, and nodes ND31 to ND38.

Incidentally, while the FETs 31 to 33 are each shown as two cascaded FETs, the FETs 31 to 33 will each be described as one FET in the following.

The node ND31 is connected to a source SVDD of supply of a power supply voltage VDD.

The anode of the diode D31 is connected to the node ND31 via the resistance R31. The cathode of the diode D31 is connected to the anode of the diode D32. The node ND32 is formed by a point of connection between the cathode of the diode D31 and the anode of the diode D32.

The cathode of the diode D32 is connected to the anode of the diode D33. The node ND33 is formed by a point of connection between the cathode of the diode D32 and the anode of the diode D33. The cathode of the diode D33 is connected to the anode of the diode D34. The node ND34 is formed by a point of connection between the cathode of the diode D33 and the anode of the diode D34. The cathode of the diode D34 is connected to the output node ND35.

One terminal side of the capacitor C31 is connected to the node ND32. Another terminal side of the capacitor C31 is connected to the drain of the FET 31. The node ND36 is formed by a point of connection between the other terminal side of the capacitor C31 and the drain of the FET 31.

One terminal side of the capacitor C32 is connected to the node ND33. Another terminal side of the capacitor C32 is connected to the drain of the FET 32. The node ND37 is formed by a point of connection between the other terminal side of the capacitor C32 and the drain of the FET 32.

One terminal side of the capacitor C33 is connected to the node ND34. Another terminal side of the capacitor C33 is connected to the drain of the FET 33. The node ND38 is formed by a point of connection between the other terminal side of the capacitor C33 and the drain of the FET 33.

The sources of the FETs 31 to 33 are connected to a ground potential. The clock CLK of the positive phase is supplied to the gates of the FETs 31 and 33 in odd stages via the resistance R35. The clock /CLK of the opposite phase is supplied to the gate of the FET 32 in an even stage via the resistance R36.

The capacitor C34 is connected between the output node ND35 and the ground potential GND.

The node ND36 is connected to the node ND31 via the resistance R32. The node ND37 is connected to the node ND31 via the resistance R33. The node ND38 is connected to the node ND31 via the resistance R34.

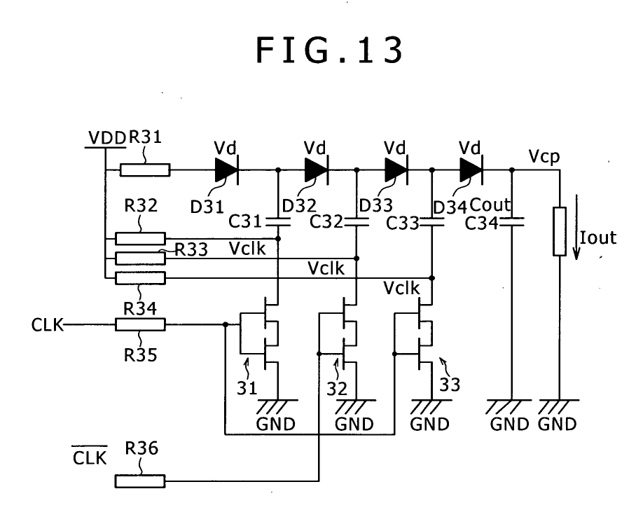

FIG. 13 is a circuit diagram showing a Dickson type charge pump circuit.

The charge pump circuit section 120 having such a configuration functions as a Dickson type charge pump circuit as shown in FIG. 12 and FIG. 13.

The raising and dropping of potentials of nodes ND32 to ND34 on the cathode sides of cascaded diodes D31 to D33 are repeated by clocks CLK and /CLK. Thereby, the potentials of the nodes ND32 to ND34 are gradually boosted, and a boosted voltage Vcp is output from an output node ND35.

The charge pump circuit section in FIG. 12 and FIG. 13 is an example of a charge pump circuit having three stages.

Letting n be the number of stages of the charge pump circuit, the generated charge pump voltage Vcp is given by the following equation.

$$Vcp = V D D + n \cdot ( {V}_{CLK} - {V}_{d} - \frac{{I}_{OUT}}{C \cdot {f}_{OSC}} ) - {V}_{d}$$

Variation in oscillation frequency fosc also varies output voltage. However, because the multivibrator circuit according to the present embodiment capable of stabilizing the oscillation frequency is applied to the oscillating circuit section 110, the output voltage can be stabilized.

The present disclosure contains subject matter related to that disclosed in Japanese Priority Patent Application JP 2010-131682 filed in the Japan Patent Office on Jun. 9, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A multivibrator circuit comprising:
a first field effect transistor having a source connected to a ground potential;
a second field effect transistor having a source connected to the ground potential;
a first resistance connected between a drain of said first field effect transistor and a source of supply of a power supply voltage;
a second resistance connected between a drain of said second field effect transistor and the source of supply of the power supply voltage;
a third resistance connected between a gate of said second field effect transistor and the source of supply of the power supply voltage;
a fourth resistance connected between a gate of said first field effect transistor and the source of supply of the power supply voltage;
a first capacitor connected between the drain of said first field effect transistor and the gate of said second field effect transistor, and forming an integrating circuit with said third resistance;
a second capacitor connected between the drain of said second field effect transistor and the gate of said first field effect transistor, and forming an integrating circuit with said fourth resistance;
a diode-connected third field effect transistor connected between the gate of said first field effect transistor and the ground potential; and
a diode-connected fourth field effect transistor connected between the gate of said second field effect transistor and the ground potential.

2. The multivibrator circuit according to claim 1,
wherein a fifth resistance is connected in a path of connection between a gate and a drain of said third field effect transistor, and the drain of said third field effect transistor is connected to the gate of said first field effect transistor.

3. The multivibrator circuit according to claim 1,
wherein a sixth resistance is connected in a path of connection between a gate and a drain of said fourth field effect transistor, and the drain of said fourth field effect transistor is connected to the gate of said second field effect transistor.

4. The multivibrator circuit according to claim 1, further comprising
a seventh resistance for bias adjustment, the seventh resistance being connected between a source of said third field effect transistor and the ground potential.

5. The multivibrator circuit according to claim 1, further comprising
an eighth resistance for bias adjustment, the eighth resistance being connected between a source of said fourth field effect transistor and the ground potential.

6. A voltage converting circuit comprising:
an oscillating circuit section including a multivibrator circuit configured to generate a clock of a positive phase and a clock in opposite phase from the clock of the positive phase; and
a voltage generating section configured to generate and outputting a voltage different from a supplied voltage according to the clocks of the positive phase and the opposite phase, the clocks of the positive phase and the opposite phase being supplied from said oscillating circuit section;
wherein said multivibrator circuit of said oscillating circuit section includes
a first field effect transistor having a source connected to a ground potential,
a second field effect transistor having a source connected to the ground potential,
a first resistance connected between a drain of said first field effect transistor and a source of supply of a power supply voltage,
a second resistance connected between a drain of said second field effect transistor and the source of supply of the power supply voltage,
a third resistance connected between a gate of said second field effect transistor and the source of supply of the power supply voltage,
a fourth resistance connected between a gate of said first field effect transistor and the source of supply of the power supply voltage,
a first capacitor connected between the drain of said first field effect transistor and the gate of said second field effect transistor, and forming an integrating circuit with said third resistance,
a second capacitor connected between the drain of said second field effect transistor and the gate of said first field effect transistor, and forming an integrating circuit with said fourth resistance,
a diode-connected third field effect transistor connected between the gate of said first field effect transistor and the ground potential, and
a diode-connected fourth field effect transistor connected between the gate of said second field effect transistor and the ground potential.

7. The voltage converting circuit according to claim 6,
wherein a fifth resistance is connected in a path of connection between a gate and a drain of said third field effect transistor, and the drain of said third field effect transistor is connected to the gate of said first field effect transistor.

8. The voltage converting circuit according to claim 6,
wherein a sixth resistance is connected in a path of connection between a gate and a drain of said fourth field effect transistor, and the drain of said fourth field effect transistor is connected to the gate of said second field effect transistor.

9. The voltage converting circuit according to claim 6, further comprising
a seventh resistance for bias adjustment, the seventh resistance being connected between a source of said third field effect transistor and the ground potential.

10. The voltage converting circuit according to claim 6, further comprising
an eighth resistance for bias adjustment, the eighth resistance being connected between a source of said fourth field effect transistor and the ground potential.
